(19) United States
(12) Patent Application Publication
(10) Pub. No.: US 2025/0266760 A1
(43) Pub. Date: Aug. 21, 2025

(54) CHARGE PUMP SYSTEM AND OPERATING METHOD THEREOF, AND MEMORY DEVICE

(71) Applicant: SAMSUNG ELECTRONICS CO., LTD., Suwon-si (KR)

(72) Inventors: Yoonjae Lee, Suwon-si (KR); Kunyong Yoon, Suwon-si (KR); Sangwan Nam, Suwon-si (KR); Sangwon Shim, Suwon-si (KR)

(21) Appl. No.: 19/023,113

(22) Filed: Jan. 15, 2025

(30) Foreign Application Priority Data
Feb. 16, 2024 (KR) 10-2024-0022809

(51) Int. Cl. H02M 3/07; G11C 16/04; G11C 16/30

(52) U.S. Cl. CPC H02M 3/07; G11C 16/30; G11C 16/0483

(57) ABSTRACT

A method of operating a charge pump system includes turning off a second switch connected to a first switch and a third switch, in order to change, from a first mode to a second mode, a connection mode between a plurality of pump circuits, turning on the first switch in response to node voltages at both ends of the first switch matching each other, and turning on the third switch in response to node voltages at both ends of the third switch matching each other, in which the first switch to the third switch may be connected among the plurality of pump circuits.

### CROSS-REFERENCE TO RELATED APPLICATION(S)

This application claims priority to Korean Patent Application No. 10-2024-0022809, filed in the Korean Intellectual Property Office on Feb. 16, 2024, the disclosure of which is incorporated by reference herein in its entirety.

### BACKGROUND

Recently, as interest in technology that reduces the area of peripheral circuits of memory devices has increased in the field of memory device technology, development of chip size reduction (CSR) technology of pump circuit systems included in peripheral circuits is actively underway. A pump circuit system is a system that supplies voltage to cells in a memory cell array when a memory device is operated (e.g., program operation, read operation, etc.), and reconfigurable pump systems are widely introduced to reduce a system area. However, when the reconfigurable pump system changes the connection mode of pump circuits inside the system depending on the operating situation of the memory device or the target output voltage of the pump system (e.g., in the case of changing the connection mode of the internal pump circuits from serial mode to parallel mode), a breakdown voltage (BV) risk may occur due to a sudden short circuit between nodes with different voltages (e.g., between any one of the pump circuits and the output voltage node of the entire pump system). Accordingly, it is necessary to develop a scheme for solving this problem.

### SUMMARY

In general, in some aspects, the present disclosure is directed toward a charge pump system and an operating method thereof and a memory device, which prevent a breakdown voltage (BV) risk generated when a connection mode of pump circuits in a system is changed (e.g., in the case of a change from a serial mode to a parallel mode, or the like).

According to some implementations, the present disclosure is directed to an operating method of a charge pump system, the method including turning off a second switch connected to a first switch and a third switch, in order to change, from a first mode to a second mode, a connection mode between a plurality of pump circuits, turning on the first switch in response to node voltages at both ends of the first switch matching each other, and turning on the third switch in response to node voltages at both ends of the third switch matching each other, wherein the first switch to the third switch may be connected among the plurality of pump circuits.

According to some implementations, the present disclosure is directed to a charge pump system including a charge pump circuit including a plurality of pump circuits, a first switch, a second switch, and a third switch connected among the plurality of pump circuits, a stage control circuit, and a sensing circuit configured to sense an output voltage of the charge pump system, wherein, to change, from a first mode to a second mode, a connection mode between the plurality of pump circuits, the stage control circuit is configured to turn off the second switch, turn on the first switch in response to node voltages at both ends of the first switch matching each other, and turn on the third switch in response to node voltages at both ends of the third switch matching each other.

According to some implementations, the present disclosure is directed to a memory device including a memory cell array including a plurality of memory cells, and a voltage generator configured to supply a voltage to the memory cell array based on a charge pump system, wherein the charge pump system including a plurality of charge pump circuits and a connection unit configured to connect the plurality of charge pump circuits to each other, changes connections among the plurality of charge pump circuits by transmitting a switch enable signal to the connection unit in response to node voltages at both ends of the connection unit matching each other.

### BRIEF DESCRIPTION OF THE DRAWINGS

Example implementations will be more clearly understood from the following detailed description, taken in conjunction with the accompanying drawings.

FIG. 1 is a block diagram for describing an example of a memory device according to some implementations.

FIG. 2 is a perspective view schematically illustrating an example of a structure of the memory device of FIG. 1 according to some implementations.

FIG. 3A is a timing diagram illustrating an example of a situation in which a connection mode of a charge pump system is changed according to some implementations.

FIG. 3B is a timing diagram illustrating an example of a situation in which a connection mode of a charge pump system is changed according to some implementations.

FIG. 4 is a block diagram illustrating an example of a charge pump system according to some implementations.

FIG. 5 is a block diagram illustrating an example of a charge pump circuit according to some implementations.

FIG. 6A is a block diagram illustrating an example of a connection mode of a charge pump circuit according to some implementations.

FIG. 6B is a block diagram illustrating an example of a connection mode of a charge pump circuit according to some implementations.

FIG. 7 is a timing diagram illustrating an example of an operating method of a charge pump system according to some implementations.

FIG. 8A is a circuit diagram illustrating an example of an operation of a charge pump system according to some implementations.

FIG. 8B is a timing diagram illustrating an example of an operation of a charge pump system according to some implementations.

FIG. 9A is a circuit diagram illustrating an example of an operation of a charge pump system according to some implementations.

FIG. 9B is a timing diagram illustrating an example of an operation of a charge pump system according to some implementations.

FIG. 10 is a flowchart illustrating an example of an operating method of a charge pump system according to some implementations.

### DETAILED DESCRIPTION

Hereinafter, example implementations will be described in detail with reference to the accompanying drawings.

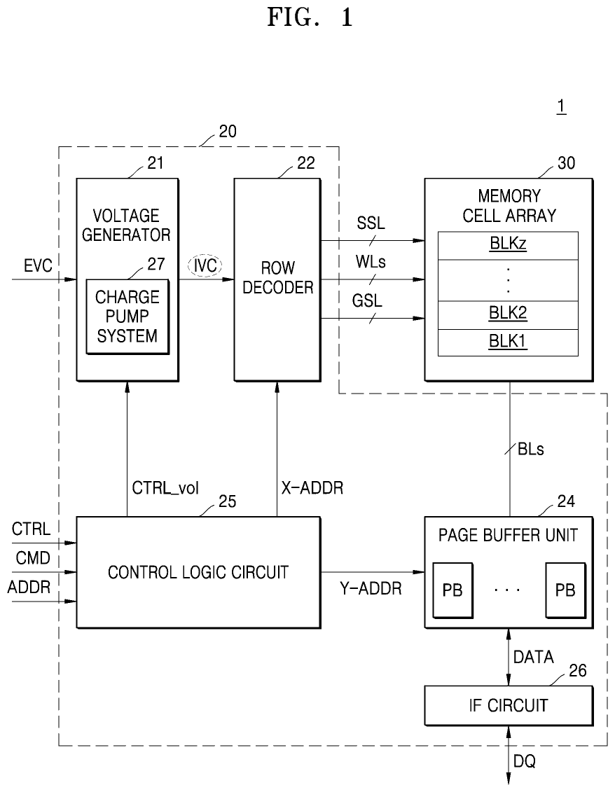

FIG. 1 is a block diagram for describing an example of a memory device according to some implementations. In FIG. 1, a memory device 1 may include a voltage generator 21, a row decoder 22, a page buffer unit 24, a control logic circuit 25, an interface (IF) circuit 26, a charge pump system 27, and a memory cell array 30. The voltage generator 21, the row decoder 22, the page buffer unit 24, the control logic circuit 25, the IF circuit 26, and the charge pump system 27 may be included in a peripheral circuit 20.

The memory device 1 may include NAND flash memory, vertical NAND (VNAND), NOR flash memory, Resistive Random Access Memory (RRAM), Phase-Change Memory (PRAM), Magnetoresistive Random Access Memory (MRAM), Ferroelectric Random Access Memory (FRAM), Spin Transfer Torque Random Access Memory (STT-RAM), etc. In addition, the memory device 1 may be implemented in a three-dimensional array structure. The memory device according to the present disclosure is applicable not only to a flash memory device in which a charge storage layer includes a conductive floating gate, but also to a charge trap flash (CTF) in which a charge storage layer includes an insulating layer. Hereinafter, for convenience of description, the memory device 1 will be referred to as a vertical NAND flash memory device (VNAND).

The memory cell array 30 may include a plurality of memory blocks BLK1 to BLKz (where z is an integer of 2 or more). Each of the memory blocks BLK1 to BLKz is connected to the row decoder 22 through word lines WL, at least one string selection line SSL, and at least one ground selection line GSL, and is connected to the page buffer unit 24 through bit lines BL. Here, the word lines WL may be implemented in a stacked plate shape.

Each of a plurality of memory blocks BLK1 to BLKz includes a plurality of strings having a three-dimensional structure arranged in a first direction and a second direction (different from the first direction) on a substrate and arranged in a third direction (a direction perpendicular to a plane formed in the first and second directions). Here, each of the plurality of strings includes at least one string selection transistor, a plurality of memory cells, and at least one ground selection transistor connected in series between a bit line and a common source line (CSL). Here, each of the plurality of memory cells may store at least one bit. In some implementations, at least one dummy cell may be included between at least one string selection transistor and the plurality of memory cells. In some implementations, at least one dummy cell may be included between the plurality of memory cells and at least one ground selection transistor.

The control logic circuit 25 may control various operations in the memory device 1 as a whole. The control logic circuit 25 may output various control signals in response to a command CMD and/or an address ADDR from the IF circuit 26. For example, the control logic circuit 25 may output a voltage control signal CTRL_vol, a row address X-ADDR, and a column address Y-ADDR.

The row decoder 22 may select one of the plurality of memory blocks BLK1 to BLKz in response to the row address X-ADDR. In addition, the row decoder 22 may be connected to the memory cell array 30 through word lines WL, at least one string selection line SSL, and at least one ground selection line GSL. The row decoder 22 may select the word lines WL, the string selection line SSL, and the ground selection line GSL using the row address X-ADDR.

The page buffer unit 24 may be connected to the memory cell array 30 through the bit lines BL. The page buffer unit 24 may be implemented to receive a column address Y-ADDR. The page buffer unit 24 may select the bit lines BL using the column address Y-ADDR.

The page buffer unit 24 may receive data from the IF circuit 26 and store the input data in the memory cell array 30. In addition, the page buffer unit 24 may read data from the memory cell array 30 and provide the read data to the IF circuit 26. The IF circuit 26 may transmit/receive data through a DQ pin.

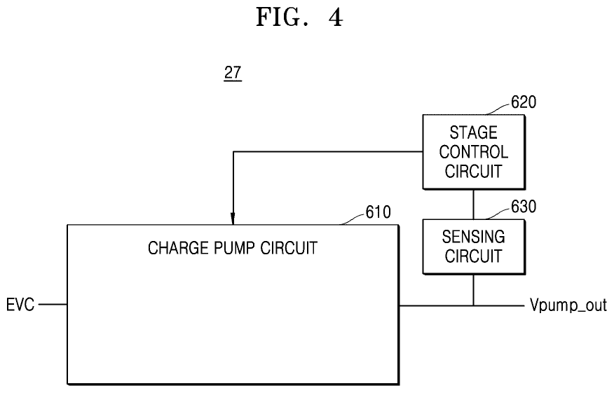

The voltage generator 21 may include the charge pump system 27. The charge pump system 27 is a kind of DC-DC converter, and may generate an output voltage IVC by stepping-up or stepping-down an input voltage EVC. The output voltage IVC may be at least one of driving voltages applied to the string selection line SSL, the word lines WL, and the ground selection line GSL. The charge pump system 27 may control the level of the output voltage IVC by adjusting the number of pump circuits (or pump stages) receiving the input voltage EVC. The charge pump system 27 may be described in detail with reference to FIGS. 4 to 9B.

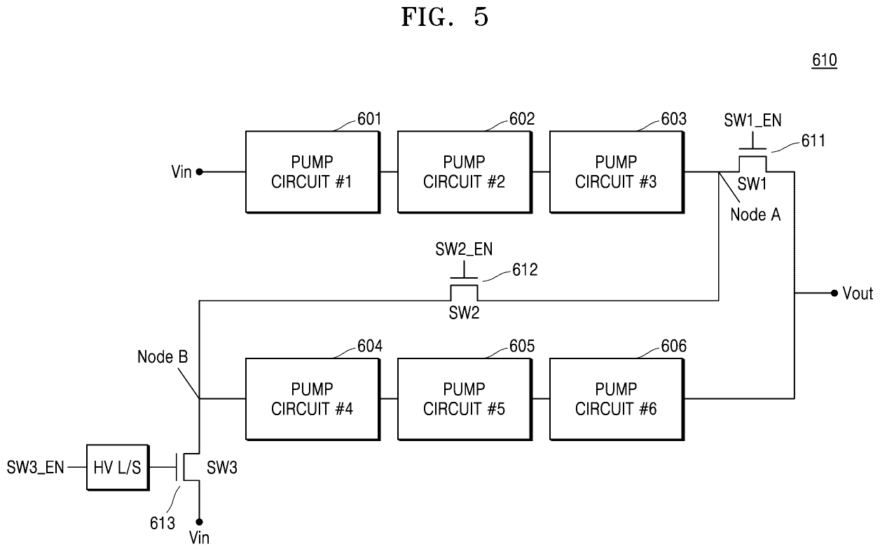

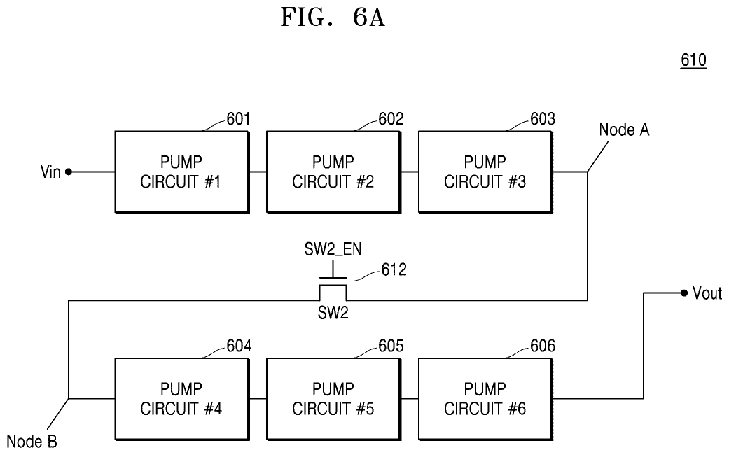

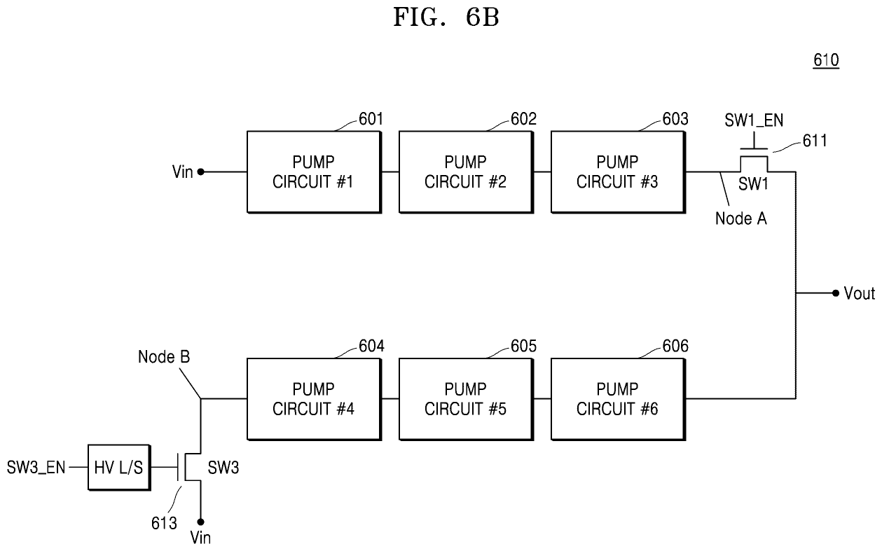

The charge pump system 27 may change a connection mode between a plurality of pump circuits included in the charge pump system 27. For example, the charge pump system 27 may switch first to third switches (see FIGS. 5 to 6B) connected among the plurality of pump circuits to change, from a first mode to a second mode, the connection mode between the plurality of pump circuits. Here, a first end of the first switch or the third switch may be connected to any one of the plurality of pump circuits, and a second end of the first switch or the third switch may be connected to an input node or an output node of the charge pump system 27. The first mode may indicate a state in which the plurality of pump circuits are connected in series, and the second mode may indicate a state in which the plurality of pump circuits are connected in parallel. However, implementations are not limited thereto, and the charge pump system 27 may change the connection mode between the plurality of pump circuits from the second mode to the first mode by switching the first to third switches connected among the plurality of pump circuits. The charge pump system 27 may generate a switch enable signal for switching the first switch and the third switch to change, from the first mode to the second mode, the connection mode between the plurality of pump circuits.

In some implementations, the charge pump system 27 may identify a target pump circuit connected to the first end of the first switch or the third switch among the plurality of pump circuits, and change (e.g., step-up or step-down) the voltage of the output node/input node of the target pump circuit until the voltage of the output node/input node of the target pump circuit matches the node voltage of the second end of the first switch or the third switch.

In some implementations, the charge pump system 27 may compare node voltages at both ends of the first switch or the third switch with each other according to a predetermined period using a comparator. When the node voltages at both ends of the first switch match each other and/or the node voltages at both ends of the third switch match each other, the stage control circuit of the charge pump system 27 may switch (e.g., turn-on) the first switch or the third switch through a switch enable signal in response to receiving a detect signal from the comparator to change the connection mode between the plurality of pump circuits.

In some implementations, the charge pump system 27 may delay the switch enable signal for a predetermined delay period by using a delay circuit. That is, the charge pump system 27 may switch (e.g., turn-on) the first switch or the third switch after the predetermined delay period to change the connection mode between the plurality of pump circuits. For example, the charge pump system 27 may change (e.g., step-up or step-down) the voltage of the output node/input node of the target pump circuit connected to the first end of the first switch or the third switch for the predetermined delay period to match the voltage of the output node/input node of the target pump circuit with the node voltage of the second end. That is, the charge pump system 27 may change the connection mode between a plurality of pump circuits while preventing a breakdown voltage (BV) risk by switching (e.g., turning on) the first switch or the third switch through a switch enable signal after matching voltages (that is, voltage levels) at both ends of the first switch or the third switch with each other during the delay period.

According to some implementations, the charge pump system 27 may change the connection mode between the plurality of pump circuits by switching the first switch or the third switch after matching the node voltages at both ends of the first switch or the third switch (see FIGS. 5 to 6B) with each other, thereby preventing the occurrence of a BV risk and improving the overall operation stability of the memory device.

According to the charge pump system 27 and an operating method thereof and the memory device according to some implementations, it is possible to prevent a BV risk that occurs when the connection mode of pump circuits inside the system is changed (e.g., change from a serial mode to a parallel mode).

Furthermore, as the BV risk is eliminated as described above, the overall operating performance and system stability of the memory device 1 may be improved by stably driving the charge pump system 27.

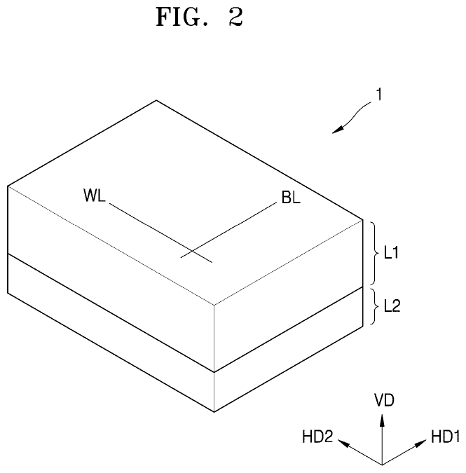

FIG. 2 is a perspective view schematically illustrating an example of a structure of the memory device of FIG. 1 according to some implementations. In FIG. 2, a Cell Over Periphery (COP) structure is illustrated as an example of the memory device 1, but the memory device 1 according to some implementations may be implemented through various structures without being limited thereto.

In FIG. 2, the memory device 1 may include a first semiconductor layer L1 and a second semiconductor layer L2, and the first semiconductor layer L1 may be stacked in a vertical direction VD with respect to the second semiconductor layer L2. Specifically, the second semiconductor layer L2 may be arranged below the first semiconductor layer L1 in the vertical direction VD, and accordingly, the second semiconductor layer L2 may be arranged close to the substrate.

In some implementations, the memory cell array 30 of FIG. 1 may be formed on the first semiconductor layer L1, and the peripheral circuit 20 of FIG. 1 may be formed on the second semiconductor layer L2. Accordingly, the memory device 1 may have a structure in which the memory cell array 30 is arranged on the peripheral circuit 20, that is, a COP structure. The COP structure may effectively reduce the horizontal area and improve the degree of integration of the memory device 1.

In some implementations, the second semiconductor layer L2 may include a substrate, and the peripheral circuit 20 may be formed in the second semiconductor layer L2 by forming transistors and metal patterns for wiring the transistors on the substrate. After the peripheral circuit 20 is formed in the second semiconductor layer L2, the first semiconductor layer L1 including the memory cell array 30 may be formed, and metal patterns for electrically connecting the word lines WL and bit lines BL of the memory cell array 30 with the peripheral circuit 20 formed in the second semiconductor layer L2 may be formed. For example, the bit lines BL may extend in the first horizontal direction HD1, and the word lines WL may extend in the second horizontal direction HD2.

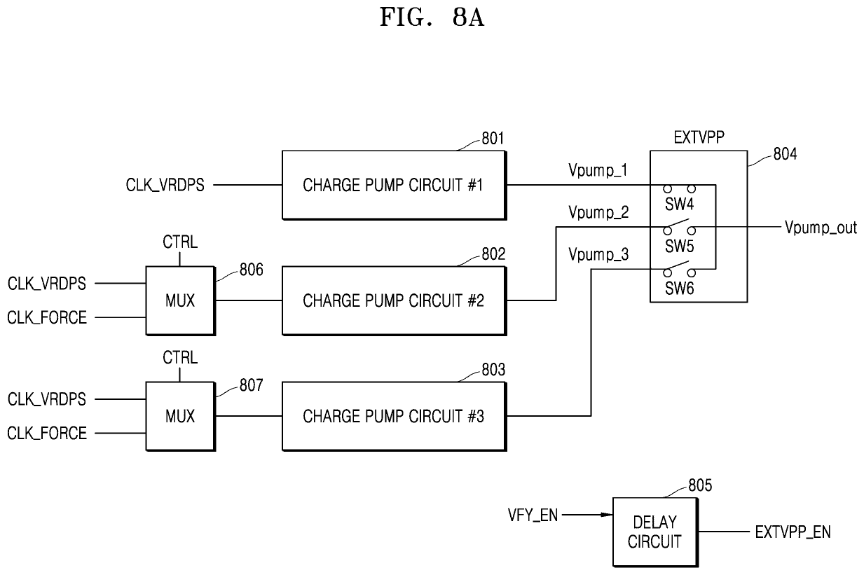

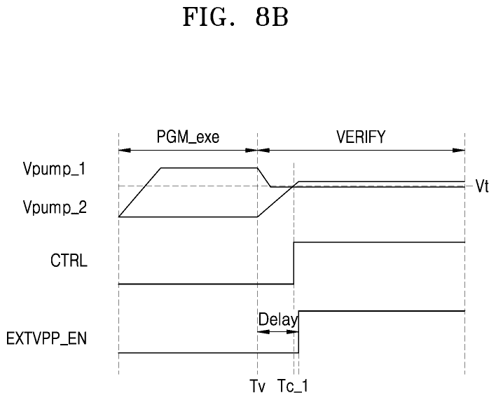

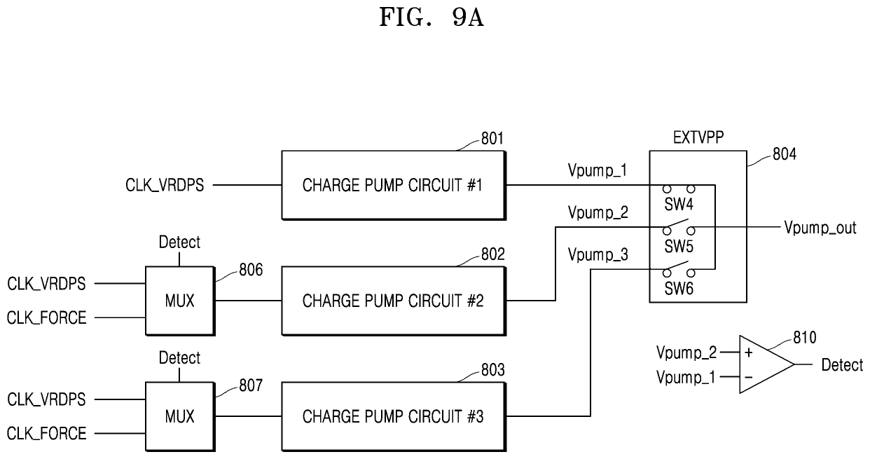

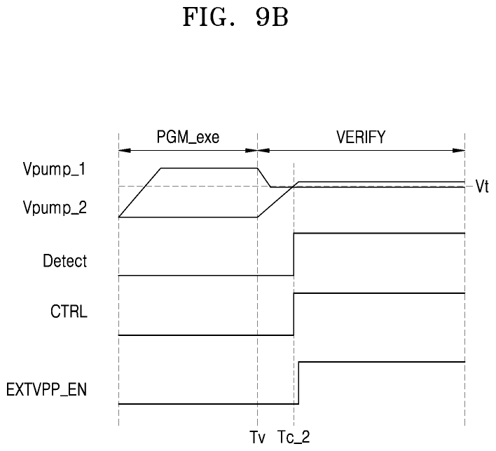

In some implementations, the peripheral circuit 20 formed in the second semiconductor layer L2 may include the voltage generator 21 including the charge pump system 27. For example, the charge pump system 27 may be a reconfigurable pump system, and the charge pump system 27 may include a plurality of pump circuits. When the connection mode between the plurality of pump circuits is changed, the charge pump system 27 may change the connection mode between the plurality of pump circuits after matching the voltages at both ends (e.g., node voltages) of a portion where the connection is changed inside the charge pump system 27 (e.g., the first switch and the third switch of FIGS. 5 to 6B, or the fifth switch and the sixth switch of FIGS. 8A and 9A, etc.).

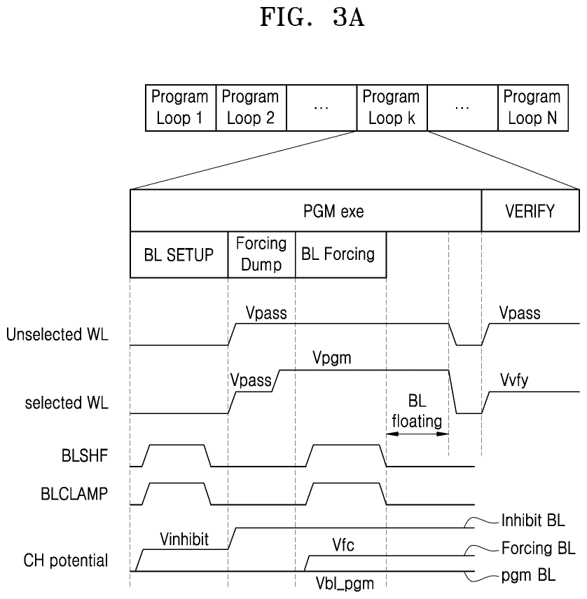

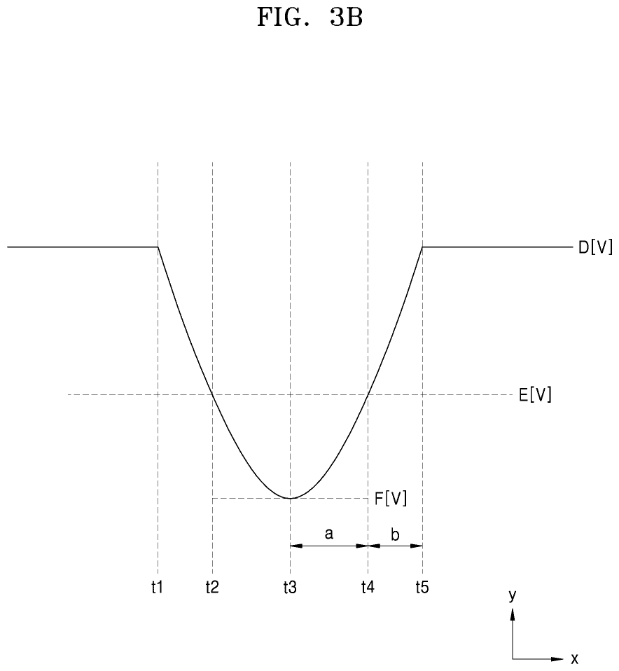

FIG. 3A is a timing diagram illustrating an example of a situation in which a connection mode of a charge pump system is changed according to some implementations. In FIG. 3A, first to N-th program loops, where N is a natural number greater than or equal to 2, may be performed during a program operation. The k-th program loop may include a program execution (PGM_exe) section and a program verification (VERIFY) section. The description of the k-th program loop may be applied to the remaining program loops. FIG. 3A may be described with reference to FIG. 1.

The program execution section may include a bit line setup (BL SETUP) section, a forcing dump (Forcing Dump) section, and a bit line forcing (BL Forcing) section. In the bit line setup section, a bit line shut-off control signal BLSHF and a bit line clamping control signal BLCLAMP may transition to turn-on levels. Additionally, a bit line selection signal may also be shifted to a turn-on level.

When the bit line setup section ends, a pass voltage Vpass may be applied to an unselected word line. When the bit line setup section ends, the pass voltage Vpass and a program voltage Vpgm may be sequentially applied to a selected word line. However, embodiments are not limited thereto, and only the program voltage Vpgm may be applied to the selected word line.

The result of the program verification section of the previous program loop may be stored in a sensing latch and a forcing latch. According to data stored in the sensing latches and the forcing latches included in the plurality of page buffers, bit lines (or CH potential) may be classified into a program inhibition bit line Inhibit BL, a forcing bit line Forcing BL, and a program allowable bit line pgm BL.

When the bit line setup section ends, the forcing dump section may be executed. In the forcing dump section, forcing data stored in the forcing latch may be transmitted to the sensing latch. In some implementations, the forcing data stored in the forcing latch may be transferred to another data latch.

When the forcing dump section ends, the bit line forcing section may be executed. In the bit line forcing section, a forcing voltage Vfc may be applied to the forcing bit line, and a bit line program allowable voltage Vbl_pgm may be applied to the program allowable bit line.

When the bit line forcing section ends, the bit line shut-off control signal BLSHF may have a turn-off level, and accordingly, the bit line BL may be floated.

In the program verify section, the pass voltage Vpass may be applied to the unselected word line. A verification voltage Vvfy may be applied to the selected word line.

The charge pump system 27 (or charge pump circuit) may generate a pass voltage Vpass applied to unselected word lines of the memory cell array in the program execution PGM_exe section and generate a pass voltage Vpass applied to unselected word lines of the memory cell array in the program verification VERIFY section.

FIG. 3B is a timing diagram illustrating an example of a situation in which a connection mode of a charge pump system is changed according to some implementations. In FIG. 3B, a change in an output voltage Vpump_out of the charge pump system 27 (e.g., the charge pump circuit 610 of FIG. 4) when the program execution PGM_exe section of FIG. 3A is changed to the program verification VRIFY section. FIG. 3B may be described with reference to FIG. 1.

In FIG. 3B, it is assumed that the horizontal axis x represents time and the vertical axis y represents the output voltage Vpump_out of the charge pump system 27 (e.g., the charge pump circuit 610). In the program verification VERIFY section, memory cells charged in the memory cell array may operate as capacitors.

The charge pump system 27 may be connected to a word line of the memory cell array 30 through a driving line. That is, the output voltage of the charge pump system 27 may be applied to the word line of the memory cell array 30 through the driving line. The charge pump system 27 may charge the driving line with a precharge voltage before the driving line and the corresponding word line are connected, and charge the driving lines with a bias voltage after the driving line and the corresponding word line are connected.

In FIGS. 3A and 3B, as the program execution PGM_exe section is changed to the program verification VERIFY section, the charge pump system 27 (e.g., the charge pump circuit) may charge a driving line to a precharge voltage D[V] before t1.

When a block selection signal is enabled at t1, the driving line and the word line are electrically connected with each other. Accordingly, the driving line voltage (i.e., the output voltage of the charge pump system 27) and the word line voltage may be lowered by the charge sharing. Here, in the case of the program verification VERIFY section, unlike the program execution PGM_exe section in which only the selected word line is turned on, all word lines are turned on, so that capacitance due to the word lines may be greatly increased. Accordingly, charge sharing between the driving line and the word line occurs, and the driving line voltage (i.e., the output voltage of the charge pump system 27) may drop significantly due to charge sharing. For example, during a section from t1 to t3, the output voltage of the charge pump system 27 may drop from D[V] to F[V].

At t3, the charge pump system 27 may change, from the first mode to the second mode, the connection mode of the charge pump circuit in order to step-up the output voltage and boost the word line to the pass voltage Vpass. For example, the charge pump system 27 may switch the first to third switches (see 611 to 613 in FIG. 5) included in the charge pump circuit to change, from the first mode to the second mode, the connection mode between the plurality of pump circuits. The first mode may represent a state in which a plurality of pump circuits included in the charge pump circuit are connected in series, and the second mode may represent a state in which the plurality of pump circuits included in the charge pump circuit are connected in parallel.

The charge pump system 27 may boost the output voltage to E[V] in a section from t3 to t4 (e.g., section a). For example, the charge pump system 27 may charge the driving line and the word line up to E[V] based on the second mode during the section a.

At t4, the charge pump system 27 may change the connection mode of the charge pump circuit from the second mode to the first mode. For example, the charge pump system 27 may switch the first to third switches included in the charge pump circuit to change the connection mode between the plurality of pump circuits from the second mode to the first mode.

In a section from t4 to t5 (e.g., section b), the charge pump system 27 may charge the driving line and the word line based on the plurality of charge pump circuits (or pump circuits) connected in the first mode. For example, the charge pump system 27 may charge the driving line and the word line up to D[V] based on the first mode during the section b.

However, when the connection mode of the charge pump circuit is changed in t3, a breakdown voltage (BV) risk may occur instantaneously as nodes (e.g., nodes at both ends of the switch) having different voltages (or voltage levels) are short-circuited in the previous connection mode (e.g., the first mode).

In some implementations, the device and method may prevent the occurrence of a BV risk by changing the connection among the plurality of charge pump circuits (or the plurality of pump circuits) after matching the voltages (or voltage levels) of nodes (e.g., nodes at both ends of the switch) having different voltages (or voltage levels) in the previous connection mode. A detailed description thereof will be given in detail with reference to FIGS. 4 to 10, which will be described later.

FIG. 4 is a block diagram illustrating an example of a charge pump system according to some implementations. The charge pump system 27 of FIG. 4 may correspond to the charge pump system 27 of FIG. 1.

In FIG. 4, the charge pump system 27 may include a charge pump circuit 610, a stage control circuit 620, and a sensing circuit 630. The charge pump system 27 may step-up or step-down an input voltage EVC to generate an output voltage Vpump_out. The output voltage Vpump_out may be the output voltage IVC of FIG. 1. The charge pump system 27 may be a circuit for generating a pass voltage applied to unselected word lines of the memory cell array in a program operation or a program verification operation of the memory device 1. However, embodiments are not limited thereto, and the charge pump system 27 may be a circuit for generating various voltages applied to the memory cell array. The charge pump system 27 may further include a comparator or a delay circuit.

The charge pump circuit 610 may include a plurality of pump circuits (e.g., the first to sixth pump circuits of FIG. 5) and first to third switches (see FIG. 5) connected among the plurality of pump circuits. A detailed description of the charge pump circuit 610 will be given in detail with reference to FIGS. 5 to 6B.

The sensing circuit 630 may sense the voltage level of the output voltage Vpump_out to compare the voltage level of the output voltage Vpump_out with a reference level, and control the stage control circuit 620 according to the comparison result. The stage control circuit 620 may control the number of activated pump circuits among the plurality of pump circuits (e.g., first to sixth pump circuits of FIG. 5) included in the charge pump circuit 610, that is, the number of stages. The stage control circuit 620 may control activation timing of a plurality of pump circuits (e.g., first to sixth pump circuits of FIG. 5).

According to some implementations, the stage control circuit 620 may switch the first switch or the third switch when the node voltages at both ends of each switch (e.g., the first switch or the third switch) included in the charge pump circuit 610 match to change the connection mode (e.g., the first mode or the second mode) among the plurality of pump circuits included in the charge pump circuit 610. The first mode may indicate a state in which the plurality of pump circuits are connected in series, and the second mode may indicate a state in which the plurality of pump circuits are connected in parallel. For example, the stage control circuit 620 may change the connection mode between the plurality of pump circuits by transmitting a switch enable signal to the first switch or the third switch in response to receiving, from a comparator of the charge pump circuit 610, a detect signal indicating that the node voltages at both ends of the first switch or the third switch match. For example, the stage control circuit 620 delays the switch enable signal by a predetermined delay period through the delay circuit of the charge pump system 27 and transmits the delayed switch enable signal to the first switch or the third switch (in this case, the charge pump system 27 prevents the occurrence of a BV risk by matching the voltage levels at both ends of each switch (e.g., the first switch or the third switch) during the delay period), thereby changing the connection mode between the plurality of pump circuits. Here, the switch enable signal is a signal generated by the stage control circuit 620 and may mean a control signal for switching the first switch or the third switch to change the connection mode between the plurality of pump circuits included in the charge pump circuit 610.

Accordingly, the charge pump system 27 may stably supply a memory operating voltage (e.g., a pass voltage or the like) to the memory cell array by removing a BV risk that may occur when a connection mode between the plurality of pump circuits is changed.

FIG. 5 is a block diagram illustrating an example of a charge pump circuit according to some implementations. In detail, FIG. 5 is a block diagram for explaining the configuration of the charge pump circuit 610 of FIG. 4.

In FIG. 5, the charge pump circuit 610 may include a plurality of pump circuits (e.g., a first pump circuit 601 to a sixth pump circuit 606), a plurality of switches connected among the plurality of pump circuits (e.g., a first switch (SW1) 611, a second switch (SW2) 612, a third switch (SW3) 613), and a high voltage level shifter (HV L/S) (which receives SW3_EN and operates). The plurality of pump circuits may include the first pump circuit 601 to the sixth pump circuit 606.

In some implementations, the charge pump circuit 610 may control the level of the output voltage Vpump_out or the slope of the output voltage Vpump_out according to the connection mode of the first pump circuit 601 to the sixth pump circuit 606. For example, the charge pump circuit 610 may pump (or step-up) the voltage level of the input voltage EVC to the target output voltage level based on the plurality of pump circuits (e.g., the first pump circuit 601 to the sixth pump circuit 606). Here, the input voltage EVC (that is, Vin) may be pumped (or stepped-up) to a predetermined voltage level each time the input voltage EVC passes through one pump circuit. For example, as the input voltage EVC passes through the first pump circuit 601, the voltage level may be pumped (or stepped-up) by about 2[V].

In some implementations, the first switch (SW1) 611, the second switch (SW2) 612, and the third switch (SW3) 613 are switched according to control signals (e.g., switch enable signals SW1_EN, SW2_EN, and SW3_EN) received from the stage control circuit 620 to change the connection mode between the plurality of pump circuits (e.g., the first pump circuit 601 to the sixth pump circuit 606).

In some implementations, the first switch (SW1) 611 may be connected to a node A (e.g., an output node of the third pump circuit 603) and an output node Vout of the charge pump circuit 610. When the first switch (SW1) 611 is turned off, the charge pump circuit 610 may operate in a first mode (e.g., a serial connection mode), and when the first switch (SW1) 611 is turned on, the charge pump circuit 610 may operate in a second mode (e.g., a parallel connection mode). The second switch (SW2) 612 may be connected to node A (e.g., an output node of the third pump circuit 603) and node B (e.g., an input node of the fourth pump circuit 604). When the second switch (SW2) 612 is turned on, the charge pump circuit 610 may operate in the first mode (e.g., the serial connection mode), and when the second switch (SW2) 612 is turned off, the charge pump circuit 610 may operate in the second mode (e.g., the parallel connection mode). The third switch (SW3) 613 may be connected to the input node Vin of the charge pump circuit 610 and the node B (e.g., the input node of the fourth pump circuit 604). When the third switch (SW3) 613 is turned off, the charge pump circuit 610 may operate in the first mode (e.g., the serial connection mode), and when the third switch (SW3) 613 is turned on, the charge pump circuit 610 may operate in the second mode (e.g., a parallel connection mode). A detailed description of the connection mode (e.g., the first mode and the second mode) of the charge pump circuit 610 will be given below with reference to FIGS. 6A and 6B.

For convenience of explanation in FIG. 5, it has been described that the charge pump circuit 610 includes the first pump circuit 601 to the sixth pump circuit 606, but is not limited thereto, and the charge pump circuit 610 may include various numbers of pump circuits.

For convenience of explanation in FIG. 5, it is shown that the first switch (SW1) 611 is located between the third pump circuit 603 and the output node Vout, the second switch (SW2) 612 is located between the third pump circuit 603 (or node A) and the fourth pump circuit 604 (or node B), and the third switch (SW3) 613 is located between the fourth pump circuit 604 and the input node Vin, but the present disclosure is not limited thereto. The first switch (SW1) 611 to the third switch (SW3) 613 according to an embodiment may be arranged at various positions among the plurality of pump circuits according to a configuration/operation of a reconfigurable charge pump circuit.

In FIG. 5, the charge pump circuit 610 (or the charge pump system 27) may further include at least one of a comparator, a delay circuit, or a combination thereof. The description of the charge pump circuit 610 (or the charge pump system 27) including a comparator is given below with reference to FIGS. 8A to 8B, and the description of the charge pump circuit 610 (or the charge pump system 27) including a delay circuit is given below with reference to FIGS. 9A to 9B.

FIG. 6A is a block diagram illustrating an example of a connection mode of a charge pump circuit according to some implementations.

In FIG. 6A, a connection mode of the charge pump circuit 610 of FIG. 5 is the first mode (e.g., the serial connection mode). In FIG. 6A, it is assumed that the first switch (SW1) 611 is turned off, the second switch (SW2) 612 is turned on, and the third switch (SW3) 613 is turned off.

In FIG. 6A, an input voltage (e.g., EVC in FIG. 1) of the charge pump circuit 610 may be input to the first pump circuit 601 through the input node Vin of the charge pump circuit 610, the output of the first pump circuit 601 may be input to the second pump circuit 602, the output of the second pump circuit 602 may be input to the third pump circuit 603, the output of the third pump circuit 603 may be input to the fourth pump circuit 604 through the turned-on second switch (SW2) 612 (i.e., node A and node B are short-circuited), the output of the fourth pump circuit 604 may be input to the fifth pump circuit 605, the output of the fifth pump circuit 605 may be input to the sixth pump circuit 606, and the output of the sixth pump circuit 606 may be connected to the output node Vout of the charge pump circuit 610. For example, in t4 of FIG. 3B, the charge pump circuit 610 may change from the second mode to the first mode according to a control signal (e.g., a switch enable signal) received from the stage control circuit 620.

For convenience of explanation in FIG. 6A, it has been described that the charge pump circuit 610 includes the first pump circuit 601 to the sixth pump circuit 606, but is not limited thereto, and the charge pump circuit 610 may include various numbers of pump circuits.

For convenience of explanation in FIG. 6A, it is shown that the first switch (SW1) 611 is located between the third pump circuit 603 and the output node Vout, the second switch (SW2) 612 is located between the third pump circuit 603 (or node A) and the fourth pump circuit 604 (or node B), and the third switch (SW3) 613 is located between the fourth pump circuit 604 and the input node Vin, but the present disclosure is are not limited thereto. The first switch (SW1) 611 to the third switch (SW3) 613 according to an embodiment may be arranged at various positions among the plurality of pump circuits according to a configuration/operation of a reconfigurable charge pump circuit.

FIG. 6B is a block diagram illustrating an example of a connection mode of a charge pump circuit according to some implementations.

In FIG. 6B, a connection mode of the charge pump circuit 610 of FIG. 5 is the first mode (e.g., the parallel connection mode). In FIG. 6B, it is assumed that the first switch (SW1) 611 is turned on, the second switch (SW2) 612 is turned off, and the third switch (SW3) 613 is turned on.

In FIG. 6B, the input node Vin (e.g., EVC applied in FIG. 1) of the charge pump circuit 610 may be input to the first pump circuit 601, the output of the first pump circuit 601 may be input to the second pump circuit 602, the output of the second pump circuit 602 may be input to the third pump circuit 603, the output of the third pump circuit 603 may be input to the output node Vout of the charge pump circuit 610 through the turned-on first switch (SW1) 611 (i.e., node A and the output node Vout of the charge pump circuit 610 are short-circuited), the input node Vin of the charge pump circuit 610 may be input to the fourth pump circuit 604 through the turned-on third switch (SW3) 613 (i.e., node B and the input node Vin of the charge pump circuit 610 are short-circuited), the output of the fourth pump circuit 604 may be input to the fifth pump circuit 605, the output of the fifth pump circuit 605 may be input to the sixth pump circuit 606, and the output of the sixth pump circuit 606 may be connected to the output node Vout of the charge pump circuit 610. For example, in t3 of FIG. 3B, the charge pump circuit 610 may change the first mode to the second mode according to a control signal (e.g., a switch enable signal) received from the stage control circuit 620.

For convenience of explanation in FIG. 6B, it has been described that the charge pump circuit 610 includes the first pump circuit 601 to the sixth pump circuit 606, but is not limited thereto, and the charge pump circuit 610 may include various numbers of pump circuits.

For convenience of explanation in FIG. 6B, it is shown that the first switch (SW1) 611 is located between the third pump circuit 603 and the output node Vout, the second switch (SW2) 612 is located between the third pump circuit 603 (or node A) and the fourth pump circuit 604 (or node B), and the third switch (SW3) 613 is located between the fourth pump circuit 604 and the input node Vin, but the present disclosure is not limited thereto. The first switch (SW1) 611 to the third switch (SW3) 613 according to an embodiment may be arranged at various positions among the plurality of pump circuits according to a configuration/operation of a reconfigurable charge pump circuit.

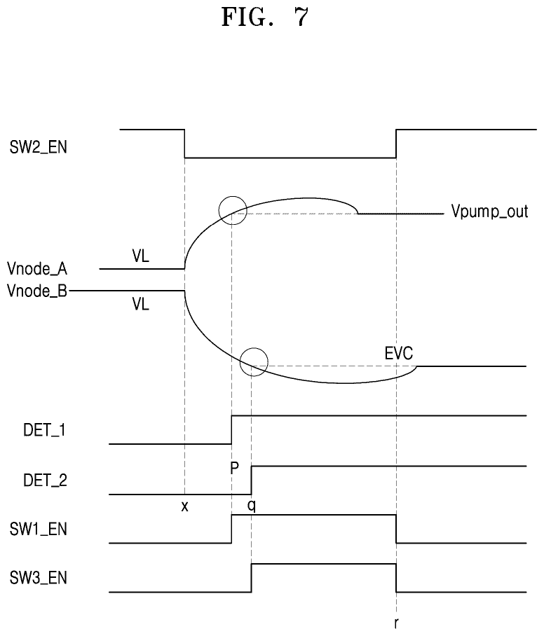

FIG. 7 is a timing diagram illustrating an example of an operating method of a charge pump system according to some implementations.

In FIG. 7, an operation method of the charge pump system 27 for preventing a breakdown voltage (BV) risk when the connection mode of the charge pump circuit 610 is changed from the first mode of FIG. 6A to the second mode of FIG. 6B.

In FIG. 7, the charge pump system 27 (or the charge pump circuit 610) further includes a first comparator and a second comparator, wherein the first comparator may compare node voltages at both ends of the first switch (SW1) 611 (e.g., a voltage at node A and an output voltage Vout of the charge pump circuit 610 (e.g., Vpump_out of the charge pump circuit 610)) (see FIG. 5) to generate a first detect signal DET_1, and the second comparator may compare node voltages at both ends of the third switch (SW3) 613 (e.g., a voltage of the node B and a voltage at an input node Vin of the charge pump circuit 610 (e.g., EVC of FIG. 1)) (see FIG. 5) to generate a second detect signal DET_2. Each of the first comparator and the second comparator may include a logic circuit capable of inverting node voltages (i.e., input data of the comparators) at both ends of the first switch (SW1) 611 or the third switch (SW3) 613 to perform a comparison operation regardless of the tendency of changes in node voltages at both ends of the first switch (SW1) 611 or the third switch (SW3) 613 input to each comparator.

In FIG. 7, a first switch enable signal SW1_EN to a third switch enable signal SW3_EN may be control signals generated by the stage control circuit 620 to switch the first switch (SW1) 611 to the third switch (SW3) 613 (when the connection mode of the charge pump circuit 610 is changed). The first switch enable signal SW1_EN transitions from the low level to the high level in order to turn on the first switch (SW1) 611. The second switch enable signal SW2_EN transitions from the low level to the high level in order to turn on the second switch (SW2) 612. The third switch enable signal SW3_EN transitions from the low level to the high level in order to turn on the third switch (SW3) 613.

In FIG. 7, Vnode_A may represent a node voltage at node A, and Vnode_B may represent a node voltage at node B. The first detect signal DET_1 transitions from the low level to the high level when the node voltages at both ends of the first switch SW1 (611) (e.g., the voltage at the node A and the voltage at the output node Vout of the charge pump circuit 610 (e.g., the output voltage Vpump_out of the charge pump circuit 610)) are compared with each other and both match. The second detection signal DET_2 transitions from the low level to the high level when the node voltages at both ends of the third switch (SW3) 613 (e.g., the voltage of the node B and the voltage at the input node Vin (e.g., EVC of FIG. 1) of the charge pump circuit 610) are compared with each other and both match.

In FIGS. 5 and 7, as the second switch enable signal SW2_EN transitions from the high level to the low level at the time point x, the second switch (SW2) 612 may be turned off. As the second switch (SW2) 612 is turned off, the connection mode of the charge pump circuit 610 may be changed from the first mode (e.g., the serial connection mode) (see FIG. 6A) to the second mode (e.g., the parallel connection mode) (see FIG. 6B).

In some implementations, the charge pump system 27 may forcibly step-up the voltage level of the Vnode_A from the time point x to match the node voltages at both ends of the first switch (SW1) 611 with each other. In FIG. 5B, a first end of the first switch (SW1) 611 is connected to node A, and a second end of the first switch (SW1) 611 is connected to the output node Vout of the charge pump circuit 610. Accordingly, the charge pump system 27 may forcibly step-up the voltage level of Vnode_A until the voltage level of Vnode_A matches the voltage level (e.g., Vpump_out) at the output node Vout of the charge pump circuit 610 in order to match the voltage levels of the node voltages at both ends of the first switch (SW1) 611 with each other.

The stepped-up voltage level at the Vnode_A may match a voltage level (e.g., Vpump_out) at the output node Vout of the charge pump circuit 610 at a time point p. That is, voltage levels of node voltages at both ends of the first switch (SW1) 611 may match each other at a time point p. As the voltage levels of the node voltages at both ends of the first switch (SW1) 611 match each other, the first detect signal DET_1 may transition from a low level to a high level at the time point p.

The first switch enable signal SW1_EN may also transition from the low level to the high level at the time point p. As the first switch enable signal SW1_EN transitions from the low level to the high level at the time point p, the first switch (SW1) 611 is turned on, and the node A and the output node Vout of the charge pump circuit 610 may be short-circuited (see FIG. 5B). After the time point p, the voltage level at the Vnode_A may converge to the voltage level (e.g., Vpump_out) at the output node Vout of the charge pump circuit 610 through a stabilization section.

In some implementations, the charge pump system 27 may forcibly step-down the voltage level of the Vnode_B from the time point x to match the node voltages at both ends of the third switch (SW3) 613 with each other. In FIG. 5B, a first end of the third switch (SW3) 613 is connected to node B, and a second end of the third switch (SW3) 613 is connected to the input node Vin of the charge pump circuit 610. Accordingly, the charge pump system 27 may forcibly step-down the voltage level (e.g., VL) of Vnode_B until the voltage level of Vnode_B matches the voltage level (e.g., EVC) at the input node Vin of the charge pump circuit 610 in order to match the voltage levels of the node voltages at both ends of the third switch (SW3) 613 with each other. The stepped-down voltage level at the Vnode_B may match a voltage level (e.g., EVC) at the input node Vin of the charge pump circuit 610 at a time point q. That is, voltage levels of node voltages at both ends of the third switch (SW3) 613 may match each other at the time point q. As the voltage levels of the node voltages at both ends of the third switch (SW3) 613 match each other, the second detect signal DET_2 may transition from the low level to the high level at the time point q. The third switch enable signal SW3_EN may also transition from the low level to the high level at the time point q. As the third switch enable signal SW3_EN transitions from the low level to the high level at the time point q, the third switch (SW3) 613 is turned on, and the node B and the input node Vin of the charge pump circuit 610 may be short-circuited (see FIG. 5B). After the time point q, the voltage level at the Vnode_B may converge to the voltage level (e.g., EVC) at the input node Vin of the charge pump circuit 610 through a stabilization section.

The charge pump circuit 610 may be connected (or changed) to the second mode (e.g., the parallel connection mode) as the node A and the output node Vout of the charge pump circuit 610 is short-circuited and the input node Vin of node B and charge pump circuit 610 is short-circuited (it is assumed that the charge pump circuit 610 is connected to the first mode (e.g., the serial connection mode) before the time point x).

In some implementations, as the second switch enable signal SW2_EN transitions from the low level to the high level at a time point r, the first switch enable signal SW1_EN and the third switch enable signal SW3_EN synchronized with the second switch enable signal SW2_EN may also transition from the high level to the low level. In other words, at the time point r, the first switch (SW1) 611, the third switch (SW3) 613 may be turned off again, and the second switch (SW2) 612 may be turned on again. Accordingly, the connection mode of the charge pump circuit 610 may be changed from the second mode (e.g., the parallel connection mode) (see FIG. 6B) to the first mode (e.g., the serial connection mode) (see FIG. 6B).

As described above, the charge pump system 27 and its operating method may prevent the occurrence of a breakdown voltage (BV) risk by changing the connection mode of the charge pump circuits after matching voltage levels of nodes (e.g., nodes at both ends of the first switch SW1 or nodes at both ends of the third switch SW3) having the different voltage levels (or minimizing the difference in voltage levels) in the previous connection mode when changing the connection mode of the charge pump circuits.

FIG. 8A is a circuit diagram illustrating an example of an operation of a charge pump system according to some implementations that includes an operation of changing the connection mode of the charge pump system 27 when changing from the program execution section (e.g., the PGM_exe section of FIG. 3A) to the program verification section (e.g., the VERIFY section of FIG. 3A).

In FIG. 8A, the charge pump system 27 may include a first charge pump circuit 801, a second charge pump circuit 802, a third charge pump circuit 803, a switch module EXTVPP 804, a delay circuit 805, and multiplexers (MUX) 806 and 807. Vpump_out may represent an output voltage of the charge pump system 27. Each of the first charge pump circuit 801 to the third charge pump circuit 803 of FIG. 8A may correspond to the charge pump circuit 610 of FIG. 5.

The first charge pump circuit 801 may perform pumping (or stepping-up) according to an input clock signal CLK_VRDPS based on a plurality of pump circuits to output an output voltage Vpump_1.

The second charge pump circuit 802 may pump (or step-up) an input voltage according to a clock signal received from the first MUX 806 and output the generated output voltage Vpump_2 to the memory cell array. For example, the second charge pump circuit 802 may forcibly step-up the output voltage Vpump_2 of the second charge pump circuit 802 to a target output voltage level (e.g., Vt of FIG. 8B) during a predetermined delay period (e.g., delay period of FIG. 8B) according to a clock signal CLK_FORCE), and output the stepped-up output voltage Vpump_2 (that is, the voltage levels of the node voltages at both ends of the fifth switch SW5 are matched). After the output voltage Vpump_2 is stepped-up to a target output voltage level (e.g., Vt of FIG. 8B), the second charge pump circuit 802 may output the output voltage Vpump_2 generated according to the clock signal CLK_VRDPS. The second charge pump circuit 802 may turn on the fifth switch SW5 in response to the lapse of the delay period (in this case, the voltage levels of the node voltages at both ends of the fifth switch SW5 are matched during the delay period).

The first MUX 806 may transmit, to the second charge pump circuit 802, a clock signal selected between the clock signal CLK_VRDPS and the clock signal CLK_FORCE based on a control signal CTRL. For example, when the control signal CTRL is at the low level, the first MUX 806 may select the clock signal CLK_FORCE, and when the control signal CTRL is at the high level, the first MUX 806 may select the clock signal CLK_VRDPS.

The third charge pump circuit 803 may pump (or step-up) an input voltage according to the clock signal received from the second MUX 807 and output the generated output voltage Vpump_3 to the memory cell array. For example, the third charge pump circuit 803 may forcibly step-up the output voltage Vpump_3 of the third charge pump circuit 803 to a target output voltage level (e.g., Vt of FIG. 8B) during a predetermined delay period (e.g., the delay period of FIG. 8B) according to the clock signal CLK_FORCE, and output the stepped-up output voltage Vpump_3 (that is, the voltage levels of the node voltages at both ends of the sixth switch SW6 are matched.). After the output voltage Vpump_3 is stepped-up to the target output voltage level (e.g., Vt of FIG. 8B), the third charge pump circuit 803 may output the output voltage Vpump_3 generated according to the clock signal CLK_VRDPS output from the second MUX 807. The third charge pump circuit 803 may turn on the sixth switch SW6 in response to the lapse of the delay period (in this case, the voltage levels of the node voltages at both ends of the sixth switch SW6 are matched during the delay period.).

The second MUX 807 may transmit, to the third charge pump circuit 803, a clock signal selected between the clock signal CLK_VRDPS and the clock signal CLK_FORCE based on a control signal CTRL. For example, when the control signal CTRL is at the low level, the second MUX 807 may select the clock signal CLK_FORCE, and when the control signal CTRL is at the high level, the second MUX 807 may select the clock signal CLK_VRDPS.

The switch module EXTVPP 804 may change the connection modes of the first charge pump circuit 801 to the third charge pump circuit 803 based on the fourth to sixth switches SW4 to SW6. The fourth switch SW4 may be connected to the first charge pump circuit 801, the fifth switch SW5 may be connected to the second charge pump circuit 802, and the sixth switch SW6 may be connected to the third charge pump circuit 803. For example, when changing from the program execution section to the program verification section, the fifth switch SW5 and/or the sixth switch SW6 of the switch module EXTVPP 804 may be turned on according to a switch enable signal EXTVPP_EN. The stage control circuit (not shown) of the charge pump system 27 may transmit the switch enable signal EXTVPP_EN for switching the switch module EXTVPP 804 (e.g., the fifth switch SW5 and/or the sixth switch SW6) to the switch module EXTVPP 804 (e.g., the fifth switch SW5 and/or the sixth switch SW6) in response to the lapse of the predetermined delay period (e.g., the delay period Tv to Tc_1 of FIG. 8B) (that is, the stage control circuit (not shown) may turn on the switch module EXTVPP 804 (e.g., the fifth switch SW5 and/or the sixth switch SW6) based on the switch enable signal EXTVPP_EN in response to the lapse of the predetermined delay period (e.g., the delay period Tv to Tc_1 of FIG. 8B).

The delay circuit 805 may delay the switch enable signal EXTVPP_EN for a predetermined delay period (e.g., about 300 nsec) and transmit the delayed signal EXTVPP_EN to the switch module EXTVPP 804. For example, the delay circuit 805 may delay the switch enable signal EXTVPP_EN from a level transition time point of the verification enable signal VFY_EN (e.g., a transition time point from the low level to the high level of the verification enable signal VFY_EN) by a predetermined delay period (e.g., the delay period Tv to Tc_1 of FIG. 8B).

Although FIG. 8A shows that the delay circuit 805 is located outside the first charge pump circuit 801 to the third charge pump circuit 803, the delay circuit 805 is not limited thereto, and may be located inside any one of the first charge pump circuit 801 to the third charge pump circuit 803.

FIG. 8B is a timing diagram illustrating an example of an operation of a charge pump system according to some implementations that includes an operation of changing a connection mode between the first charge pump circuit 801 and the second charge pump circuit 802 in the charge pump system 27 of FIG. 8A.

In FIGS. 8A and 8B, in the program execution section PGM_exe, the output voltage Vpump_1 of the first charge pump circuit 801 may be stepped-up by a plurality of pump circuits and applied to the memory cell array. When the program execution PGM_exe section is changed to the program verification VRIFY section, the output voltage Vpump_1 of the first charge pump circuit 801 may be stepped-down to a target output voltage level (e.g., Vt).

The output voltage Vpump_2 of the second charge pump circuit 802 may be forcibly stepped-up to a target output voltage level (e.g., Vt) according to the clock signal CLK_FORCE during a predetermined delay period (e.g., a period from Tv to Tc_1).

The control signal CTRL may transition from the low level to the high level at Tc_1. For example, as the control signal CTRL transitions to the high level at Tc_1, the first MUX 806 may select the clock signal CLK_VRDPS and transmit the selected clock signal to the second charge pump circuit 802. The second charge pump circuit 802 may output the output voltage Vpump_2 according to the clock signal CLK_VRDPS at Tc_1.

The switch enable signal EXTVPP_EN may be delayed for a delay period Delay, which is predetermined by the delay circuit 805. For example, the switch enable signal EXTVPP_EN may transition from the low level to the high level after being delayed from Tv for a predetermined delay period (e.g., a period from Tv to Tc_1). Here, Tv may indicate a transition time point of the verification enable signal. The verification enable signal may indicate a control signal for changing from the program execution PGM_exe section to the program verification VERIFY section. The fifth switch SW5 may be turned on as the switch enable signal EXTVPP_EN transitions to the high level in response to the lapse of a delay period (e.g., a period from Tv to Tc_1) at Tc_1 (i.e., the switch enable signal EXTVPP_EN is transmitted to the switch module EXTVPP 804.).

As the fifth switch SW5 is turned on at Tc_1, the first charge pump circuit 801 and the second charge pump circuit 802 may be short-circuited. At Tc_1, both the voltage levels of the node voltages (e.g., the output voltage Vpump_1 of the first charge pump circuit 801 and the output voltage Vpump_2 of the second charge pump circuit 802) at both ends of the fifth switch SW5 are Vt, so that the occurrence of the BV risk may be prevented when the first charge pump circuit 801 and the second charge pump circuit 802 are connected.

The connection (or switching) operation of the first charge pump circuit 801 and the second charge pump circuit 802 described above may be applied to the connection operation of the first charge pump circuit 801 and the third charge pump circuit 803.

The charge pump system 27 may prevent the occurrence of a BV risk by changing the connection mode between the charge pump circuits after matching the voltage levels at both ends of each switch (e.g., the first switch or the third switch) during the delay period.

The operation method for preventing a BV risk of the charge pump system 27 may also be applied even when a connection mode between the plurality of charge pump circuits is changed.

The charge pump system 27 and its operation method for changing the connection mode between the plurality of charge pump circuits based on the delay circuit 805 described above with reference to FIGS. 8A and 8B may also be applied to the charge pump system 27 and its operation method for changing the connection mode between the plurality of pump circuits in FIGS. 6A and 6B.

FIG. 9A is a circuit diagram illustrating an example of an operation of a charge pump system according to some implementations and includes an operation of changing the connection mode of the charge pump system 27 when changing from the program execution section (e.g., the PGM_exe section of FIG. 3A) to the program verification section (e.g., the VERIFY section of FIG. 3A). A description with reference to FIG. 9A redundant to that of FIG. 8A described above is omitted.

In FIG. 9A, the charge pump system 27 may include the first charge pump circuit 801, the second charge pump circuit 802, the third charge pump circuit 803, the switch module EXTVPP 804, the multiplexers (MUX) 806 and 807, and a comparator 810. A description of the first charge pump circuit 801, the second charge pump circuit 802, the third charge pump circuit 803, the switch module EXTVPP 804, and the MUXs 806 and 807 of FIG. 9A will be replaced with the description of the first charge pump circuit 801, the second charge pump circuit 802, the third charge pump circuit 803, the switch module EXTVPP 804, and the MUXs 806 and 807 of FIG. 8A described above. Vpump_out may represent an output voltage of the charge pump system 27.

The second charge pump circuit 802 may pump (or step-up) an input voltage according to a clock signal received from the first MUX 806 and output the generated output voltage Vpump_2 to the memory cell array. For example, the second charge pump circuit 802 may forcibly step-up the output voltage Vpump_2 of the second charge pump circuit 802 to a target output voltage level (e.g., Vt of FIG. 8B) according to the clock signal CLK_FORCE and output the stepped-up output voltage Vpump_2 (that is, the voltage levels of the node voltages at both ends of the fifth switch SW5 are matched.). After the output voltage Vpump_2 is stepped-up to a target output voltage level (e.g., Vt of FIG. 8B), the second charge pump circuit 802 may output the output voltage Vpump_2 generated according to the clock signal CLK_VRDPS.

The third charge pump circuit 803 may pump (or step-up) an input voltage according to the clock signal received from the first MUX 806 and output the generated output voltage Vpump_3 to the memory cell array. For example, the third charge pump circuit 803 may forcibly step-up the output voltage Vpump_3 of the third charge pump circuit 803 to a target output voltage level (e.g., Vt of FIG. 8B) according to the clock signal CLK_FORCE and output the stepped-up output voltage Vpump_3 (that is, the voltage levels of the node voltages at both ends of the sixth switch SW6 are matched.). After the output voltage Vpump_3 is stepped-up to a target output voltage level (e.g., Vt of FIG. 8B), the third charge pump circuit 803 may output the output voltage Vpump_3 generated according to the clock signal CLK_VRDPS.

The comparator 810 may compare node voltages (e.g., the output voltage Vpump_1 of the first charge pump circuit 801 and the output voltage Vpump_2 of the second charge pump circuit 802) at both ends of the fifth switch SW5 to generate a detect signal Detect. For example, the comparator 810 may receive the output voltage Vpump_1 of the first charge pump circuit 801 and the output voltage Vpump_2 of the second charge pump circuit 802 and compare the voltage levels of the output voltage Vpump_1 and the output voltage Vpump_2 with each other. When the voltage levels of the output voltage Vpump_1 and the output voltage Vpump_2 match, the comparator 810 may generate a detect signal Detect (that is, in FIG. 9B, the detect signal Detect transitions from the low level to the high level.). The stage control circuit (not shown) of the charge pump system 27 may transmit the switch enable signal EXTVPP_EN for switching the switch module EXTVPP 804 (e.g., the fifth switch SW5 and/or the sixth switch SW6) to the switch module EXTVPP 804 (e.g., the fifth switch SW5 and/or the sixth switch SW6) in response to the generation of the detect signal Detect (that is, the switch module EXTVPP 804 (e.g., the fifth switch SW5 and/or the sixth switch SW6) may be turned on in response to the generation of the detect signal Detect.).

The comparator 810 may include a high voltage (HV) comparator that detects the voltage level of a node with a relatively low voltage level (e.g., the output voltage Vpump_2 of the second charge pump circuit 802) when the connection mode is changed.

The comparator 810 may directly receive the voltage level of the output voltage Vpump_1 of the first charge pump circuit 801 and the voltage level of the output voltage Vpump_2 of the second charge pump circuit 802 without a voltage division process. Accordingly, the comparator 810 may block the occurrence of response delay due to various causes (e.g., static current, resistor-capacitor (RC) delay, etc.).

The comparator 810 may include a logic capable of inverting node voltages at both ends of the fifth switch SW5 or the sixth switch SW6 input to the comparator 810 in order to perform the comparison operation described above regardless of the tendency of changes in the node voltages at both ends of the fifth switch SW5 or the sixth switch SW6.

FIG. 9B is a timing diagram illustrating an example of an operation of a charge pump system according to some implementations and includes an operation of changing a connection mode between the first charge pump circuit 801 and the second charge pump circuit 802 in the charge pump system 27 of FIG. 9A.

In FIGS. 9A and 9B, in the program execution section PGM_exe, the output voltage Vpump_1 of the first charge pump circuit 801 may be stepped-up by a plurality of pump circuits and applied to the memory cell array. When the program execution PGM_exe section is changed to the program verification VRIFY section, the output voltage Vpump_1 of the first charge pump circuit 801 may be stepped-down to a target output voltage level (e.g., Vt).

The output voltage Vpump_2 of the second charge pump circuit 802 may be forcibly stepped-up to a target output voltage level (e.g., Vt) according to the clock signal CLK_FORCE during a period from Tv to Tc_2. Here, Tv may indicate a transition time point of the verification enable signal. The verification enable signal may indicate a control signal for changing from the program execution PGM_exe section to the program verification VERIFY section.

The detect signal Detect may transition from a low level to the high level at Tc_2. Tc_2 may denote a time point at which a voltage level of an output voltage Vpump_1 of the first charge pump circuit 801 match a voltage level of an output voltage Vpump_2 of the second charge pump circuit 802 (that is, Tc_2 denotes a time point at which the node voltages of both ends of the fifth switch SW5 match). For example, the comparator 810 may compare the voltage level of the output voltage Vpump_1 of the first charge pump circuit 801 and the voltage level of the output voltage Vpump_2 of the second charge pump circuit 802 and generate a detect signal Detect when they match.

The control signal CTRL may transition from the low level to the high level at Tc_2. For example, as the control signal CTRL transitions to the high level at Tc_2, the first MUX 806 may select the clock signal CLK_VRDPS and transmit the selected clock signal to the second charge pump circuit 802. The second charge pump circuit 802 may step-up the output voltage Vpump_2 according to the clock signal CLK_VRDPS at Tc_2.

The switch enable signal EXTVPP_EN may transition from the low level to the high level at Tc_2. As the switch enable signal EXTVPP_EN transitions to the high level at Tc_2, the fifth switch SW5 may be turned on.

As the fifth switch SW5 is turned on at Tc_2, the first charge pump circuit 801 and the second charge pump circuit 802 may be short-circuited. At Tc_2, both the voltage levels of the node voltages (e.g., the output voltage Vpump_1 of the first charge pump circuit 801 and the output voltage Vpump_2 of the second charge pump circuit 802) at both ends of the fifth switch SW5 are Vt, so that the occurrence of the BV risk may be prevented when the first charge pump circuit 801 and the second charge pump circuit 802 are connected.

The connection operation of the first charge pump circuit 801 and the second charge pump circuit 802 described above may be applied to the connection operation of the first charge pump circuit 801 and the third charge pump circuit 803.

The operation method for preventing a BV risk of the charge pump system 27 may also be applied even when a connection mode between the plurality of charge pump circuits 610 is changed.

The charge pump system 27 and its operation method for changing the connection mode between the plurality of charge pump circuits based on the comparator 810 described above with reference to FIGS. 9A and 9B may also be applied to the charge pump system 27 and its operation method for changing the connection mode between the plurality of pump circuits in FIGS. 6A and 6B.

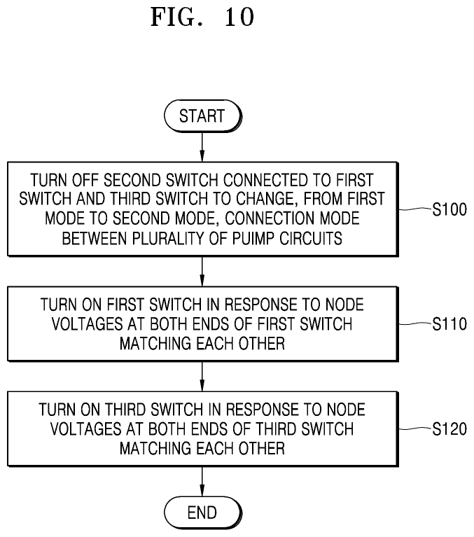

FIG. 10 is a flowchart illustrating an example of an operating method of a charge pump system according to some implementation and includes an operation method for changing a connection mode of a plurality of pump circuits in a charge pump system 27 may include operations S100 to S120. Among the descriptions of FIG. 10, redundant descriptions to those of FIGS. 1 to 9B are omitted.

In operation S100, a charge pump system 27 may turn off a second switch (e.g., the second switch 612 of FIGS. 5 to 6B) connected to a first switch and a third switch to change, from a first mode to a second mode, a connection mode between a plurality of pump circuits. Here, the first mode may indicate a state in which the plurality of pump circuits are connected in series, and the second mode may indicate a state in which the plurality of pump circuits are connected in parallel.

In operation S110, the charge pump system 27 may turn on the first switch in response to node voltages at both ends of the first switch matching each other. Here, the node voltages at both ends of the first switch may include the output voltage of the first target pump circuit (i.e., the voltage of the output node (e.g., node A of FIGS. 6A and 6B) of the first target pump circuit) and the output voltage of the charge pump system. The first target pump circuit may refer to a pump circuit (e.g., the first switch 611 of FIGS. 5 to 6B) connected to the first switch among the plurality of pump circuits.

In some implementations, the charge pump system 27 may step-up the output voltage of the first target pump circuit until the node voltages at both ends of the first switch match.

In some implementations, a first comparator of the charge pump system 27 may compare node voltages at both ends of the first switch with each other and generate a first detect signal when node voltages at both ends of the first switch match. The stage control circuit of the charge pump system 27 may transmit, to the first switch, a first switch enable signal for turning on the first switch in response to the generation of the first detect signal.

In some implementations, a delay circuit of the charge pump system 27 may delay the first switch enable signal for a predetermined delay period. Here, the first switch enable signal may refer to a control signal generated to turn on the first switch. The charge pump system 27 may step-up the output voltage of the first target pump circuit until node voltages at both ends of the first switch (or voltage levels of node voltages at both ends of the first switch) match during the delay period.

In operation S120, the charge pump system 27 may turn on the third switch in response to node voltages at both ends of the second switch matching each other. Here, the node voltages at both ends of the third switch may include the input voltage of the second target pump circuit (i.e., the voltage of the input node (e.g., node B of FIGS. 6A and 6B) of the second target pump circuit) and the input voltage of the charge pump system. The second target pump circuit may refer to a pump circuit (e.g., the third switch 613 of FIGS. 5 to 6B) connected to the third switch among the plurality of pump circuits.

In some implementations, the charge pump system 27 may step-down the input voltage of the second target pump circuit until the node voltages at both ends of the third switch match.

In some implementations, the first comparator of the charge pump system 27 may compare node voltages at both ends of the third switch with each other and generate a second detect signal when node voltages at both ends of the third switch match. The stage control circuit of the charge pump system 27 may transmit, to the third switch, a second switch enable signal for turning on the third switch in response to the generation of the second detect signal.

In some implementations, the delay circuit of the charge pump system 27 may delay the second switch enable signal for a predetermined delay period. Here, the second switch enable signal may refer to a control signal generated to turn on the third switch. The charge pump system 27 may step-down the input voltage of the second target pump circuit until the node voltages at both ends of the third switch match during the delay period.

As described above, as the first switch and the third switch are turned on and the second switch is turned off in the charge pump system 27, the connection mode between the plurality of pump circuits may be changed from the first mode (e.g., the serial connection mode) to the second mode (e.g., the parallel connection mode).

The charge pump system 27 may prevent the occurrence of a breakdown voltage (BV) risk by changing the connections between the plurality of pump circuits after matching the voltage levels of nodes (e.g., nodes at both ends of the first switch or nodes at both ends of the third switch) having different voltage levels in a previous connection mode (e.g., the first mode).

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. An operating method of a charge pump system, the method comprising:
turning off a second switch connected to both a first switch and a third switch to change, from a first mode to a second mode, a connection mode between a plurality of pump circuits;
turning on the first switch in response to node voltages matching each other at ends of the first switch; and
turning on the third switch in response to node voltages matching each other at ends of the third switch,
wherein the first switch, the second switch, and the third switch are connected among the plurality of pump circuits.

2. The method of claim 1,
wherein the first mode indicates a state in which the plurality of pump circuits are connected in series, and
wherein the second mode indicates a state in which the plurality of pump circuits are connected in parallel.

3. The method of claim 2, further comprising:
stepping-up an output voltage of a first target pump circuit until the node voltages match each other at the ends of the first switch; and
stepping-down an input voltage of a second target pump circuit until the node voltages match each other at the ends of the third switch,
wherein the first target pump circuit is configured to indicate a pump circuit connected to the first switch among the plurality of pump circuits, and
wherein the second target pump circuit is configured to indicate a pump circuit connected to the third switch among the plurality of pump circuits.

4. The method of claim 3, further comprising:
generating, based on the node voltages matching each other at the ends of the first switch, a first detect signal; and
generating, based on the node voltages matching each other at the ends of the third switch, a second detect signal.

5. The method of claim 4, further comprising:
transmitting, to the first switch, a first switch enable signal configured to turn on the first switch in response to the generating of the first detect signal; and
transmitting, to the third switch, a second switch enable signal configured to turn on the third switch in response to the generating of the second detect signal.

6. The method of claim 3,
wherein the node voltages at the ends of the first switch include an output voltage of the first target pump circuit and an output voltage of the charge pump system, and
wherein the node voltages at the ends of the third switch include an input voltage of the second target pump circuit and an input voltage of the charge pump system.

7. The method of claim 2, further comprising:
delaying the first switch enable signal and the second switch enable signal for a predetermined delay period,
wherein the first switch enable signal comprises a control signal configured to turn on the first switch, and
wherein the second switch enable signal comprises a control signal configured to turn on the third switch.

8. The method of claim 7, further comprising:
stepping-up an output voltage of a first target pump circuit of the plurality of pump circuits until the node voltages match at the ends of the first switch during the predetermined delay period;
stepping-down an input voltage of a second target pump circuit of the plurality of pump circuits until the node voltages match at the ends of the third switch during the predetermined delay period; and
turning on the first switch and the third switch based on the first switch enable signal and the second switch enable signal in response to a lapse of the predetermined delay period,
wherein the first target pump circuit is configured to indicate a pump circuit being connected to the first switch among the plurality of pump circuits, and
wherein the second target pump circuit is configured to indicate a pump circuit being connected to the third switch among the plurality of pump circuits.

9. A charge pump system comprising:
a charge pump circuit including a plurality of pump circuits, and a first switch, a second switch, and a third switch connected among the plurality of pump circuits;
a stage control circuit; and
a sensing circuit configured to sense an output voltage of the charge pump system,
wherein, to change a connection mode between the plurality of pump circuits from a first mode to a second mode, the stage control circuit is configured to:
turn off the second switch;
turn on the first switch in response to node voltages matching each other at ends of the first switch; and
turn on the third switch in response to node voltages matching each other at ends of the third switch.

10. The charge pump system of claim 9,
wherein the first mode indicates a state in which the plurality of pump circuits are connected in series, and
wherein the second mode indicates a state in which the plurality of pump circuits are connected in parallel.

11. The charge pump system of claim 10, wherein the charge pump circuit is further configured to:
step-up an output voltage of a first target pump circuit until the node voltages match at the ends of the first switch; and
step-down an input voltage of a second target pump circuit until the node voltages match at the ends of the third switch,
wherein the first target pump circuit is configured to indicate a pump circuit being connected to the first switch among the plurality of pump circuits, and
wherein the second target pump circuit is configured to indicate a pump circuit being connected to the third switch among the plurality of pump circuits.

12. The charge pump system of claim 11, further comprising a first comparator and a second comparator,
wherein the first comparator is configured to generate, based on the node voltages matching each other at the ends of the first switch, a first detect signal, and
wherein the second comparator is configured to generate, based on the node voltages matching each other at the ends of the third switch, a second detect signal.

13. The charge pump system of claim 12, wherein the stage control circuit is further configured to:
transmit, to the first switch, a first switch enable signal configured to turn on the first switch in response to the generating of the first detect signal; and
transmit, to the third switch, a second switch enable signal configured to turn on the third switch in response to the generating of the second detect signal.

14. The charge pump system of claim 12,
wherein the first comparator includes a first logic circuit configured to invert the node voltages at the first switch that are input to the first comparator, and
wherein the second comparator includes a second logic circuit configured to invert the node voltages at the ends of the third switch that are input to the second comparator.

15. The charge pump system of claim 10, further comprising:
a delay circuit,
wherein the delay circuit is configured to delay a first switch enable signal and a second switch enable signal for a predetermined delay period,
wherein the first switch enable signal comprises a control signal generated by the stage control circuit to turn on the first switch, and
wherein the second switch enable signal comprises a control signal generated by the stage control circuit to turn on the third switch.

16. The charge pump system of claim 15, wherein the charge pump circuit is further configured to:
step-up an output voltage of a first target pump circuit of the plurality of pump circuits until the node voltages of the ends of the first switch match each other during the predetermined delay period;
step-down an input voltage of a second target pump circuit of the plurality of pump circuits until the node voltages of the ends of the third switch match each other during the predetermined delay period; and
turn on the first switch and the third switch based on the first switch enable signal and the second switch enable signal in response to a lapse of the predetermined delay period,
wherein the first target pump circuit is configured to indicate a pump circuit being connected to the first switch among the plurality of pump circuits, and
wherein the second target pump circuit is configured to indicate a pump circuit being connected to the third switch among the plurality of pump circuits.

17. The charge pump system of claim 11,
wherein the node voltages at the ends of the first switch include an output voltage of the first target pump circuit and an output voltage of the charge pump system, and
wherein the node voltages at the ends of the third switch include an input voltage of the second target pump circuit and an input voltage of the charge pump system.

18. A memory device comprising:
a memory cell array including a plurality of memory cells; and
a voltage generator configured to supply a voltage to the memory cell array based on a charge pump system,
wherein the charge pump system includes a plurality of charge pump circuits and a connection unit and is configured to connect the plurality of charge pump circuits to each other, and
wherein the charge pump system is configured to change connections among the plurality of charge pump circuits by transmitting a switch enable signal to the connection unit in response to node voltages matching at ends of the connection unit.

19. The memory device of claim 18,
wherein the charge pump system further includes a comparator configured to generate a detect signal by comparing each of the node voltages at the ends of the connection unit,
wherein the detect signal comprises a signal indicating that the node voltages match each other at the ends of the connection unit, and
wherein the charge pump system is further configured to step-up or step-down a voltage of a charge pump circuit connected to the connection unit until the detect signal is generated from the comparator.

20. The memory device of claim 18,
wherein the charge pump system further includes a delay circuit configured to delay the switch enable signal by a delay period, and
wherein the charge pump system is further configured to step-up or step-down a voltage of a charge pump circuit connected to the connection unit during the delay period to match the node voltages at the ends of the connection unit.
